(19) United States
(12) Patent Application Publication
(10) Pub. No.: US 2011/0084374 A1
(43) Pub. Date: Apr. 14, 2011

(54) SEMICONDUCTOR PACKAGE WITH SECTIONED BONDING WIRE SCHEME

(76) Inventor: Jen-Chung Chen, Taipei County (TW)

(21) Appl. No.: 12/576,220

(22) Filed: Oct. 8, 2009

(51) Int. Cl. H01L 23/488

(52) U.S. Cl. 257/690; 257/E23.023

(57) ABSTRACT

A semiconductor package includes a carrier substrate having thereon at least one bond finger; a semiconductor die mounted on a top surface of the carrier substrate; at least one active bond pad disposed on the semiconductor die; at least one dummy bond pad disposed on the semiconductor die; a first bonding wire extending between the at least one active bond pad and the at least one dummy bond pad; a second bonding wire extending between the at least one dummy bond pad and the at least one bond finger; and a molding compound encapsulating at least the semiconductor die.

### BACKGROUND OF THE INVENTION

1. Field of the Invention

The present invention relates generally to semiconductor packages. More specifically, the present invention relates to a fine-pitched integrated circuit (IC) package with a sectioned bonding wire scheme that is capable of minimizing or eliminating bonding wire sweep during the encapsulating process.

2. Description of the Prior Art

In the integrated circuit (IC) packaging industry, there is a continuous desire to provide higher and higher density IC packages for semiconductor die having increasing numbers of input/output (I/O) terminal pads. When using a conventional wire bonding packaging technique, the pitch, or spacing between adjacent bonding wires becomes finer and finer as the number of I/O terminal pads increases for a given size die. This presents the problem of having two adjacent bonding wires electrically short to one another due to bonding wire sweep during the encapsulating process of producing the IC package.

During the molding or encapsulation of a plastic IC package, the flow of a plastic molding compound melt into a mold cavity exerts forces sufficiently high as to displace or deform the bond wires, hence resulting in the bonding wire sweep, which is believed to be the predominant cause of defects in the molding of IC packages. Wire sweep is typically defined as the linear deviation of the bond wire from a straight line drawn between the bond pad and the bond finger as projected on the plane of the carrier substrate. The ensuing wire deformation can cause adjacent bond wires to come into contact with each other, or they may collapse onto an electrically active part of the chip, both of which cause the device to be electrically shorted.

Although a variety of approaches have been suggested for reducing the bonding wire sweep during the encapsulating process of an IC package, many of these approaches require additional process steps or require specialized equipment. These requirements for additional process steps or specialized equipment add to the costs of producing the package and are therefore undesirable.

### SUMMARY OF THE INVENTION

It is therefore an objective of this invention to provide a wire-bonded semiconductor package with a sectioned bonding wire scheme and dummy die bond pads capable of minimizing wire sweep during the encapsulating process of a fine pitch integrated circuit package.

In one aspect, the present invention provides a semiconductor package including a carrier substrate having thereon at least one bond finger; a semiconductor die mounted on a top surface of the carrier substrate; at least one active bond pad disposed on the semiconductor die; at least one dummy bond pad disposed on the semiconductor die; a first bonding wire extending between the at least one active bond pad and the at least one dummy bond pad; a second bonding wire extending between the at least one dummy bond pad and the at least one bond finger; and a molding compound encapsulating at least the semiconductor die.

In another aspect, the present invention provides a three-dimensional semiconductor package including a carrier substrate having thereon at least one bond finger; a multiple-die stack comprising a first semiconductor die mounted on a top surface of the carrier substrate, and a second semiconductor die stacked on the first semiconductor die; at least one active bond pad disposed on the second semiconductor die; at least one dummy bond pad disposed on the second semiconductor die; a first bonding wire extending between the at least one active bond pad and the at least one dummy bond pad; a second bonding wire extending between the at least one dummy bond pad and the at least one bond finger; and a molding compound encapsulating at least the multiple-die stack.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view of a semiconductor package showing the sectioned bonding wire scheme and dummy die bond pads in accordance with one embodiment of this invention.

FIG. 2A is a schematic top view of a three-dimensional (3D) semiconductor package showing the sectioned bonding wire scheme and dummy die bond pads in accordance with another embodiment of this invention.

FIG. 2B is a schematic, cross-sectional view taken along line I-I′ of FIG. 2A.

### DETAILED DESCRIPTION

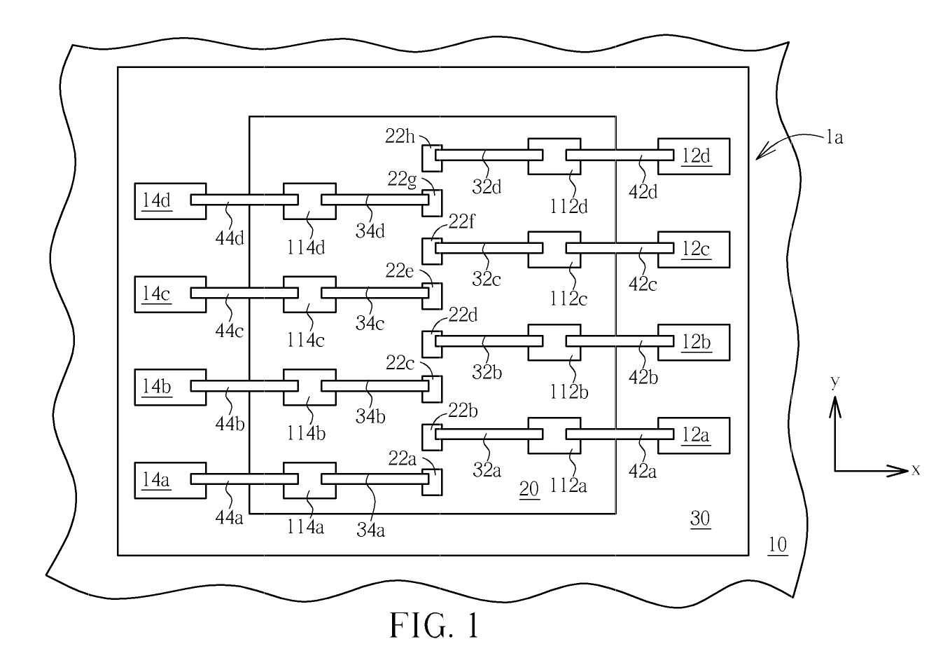

FIG. 1 is a schematic top view of a semiconductor package in accordance with one embodiment of this invention. As shown in FIG. 1, a semiconductor package 1a includes a carrier substrate 10 such as a conventional package substrate, a semiconductor die 20 mounted on a top surface of the carrier substrate 10, and a molding compound 30 encapsulating at least the semiconductor die 20.

At least two rows of bond fingers 12a-12d and 14a-14d are provided on the top surface of the carrier substrate 10. According to this embodiment, the bond fingers 12a-12d are aligned in a straight line at one side edge of the semiconductor die 20 along the reference y-axis. The bond fingers 14a-14d are aligned in a row at another side edge of the semiconductor die 20 opposite to the row of the bond fingers 12a-12d.

According to this embodiment, a plurality of active bond pads 22a-22g, which are arranged in a row, are provided on an active top surface and are disposed at the center of the semiconductor die 20. According to this embodiment, the bond pads 22a-22g are aligned in a straight line along the reference y-axis at the center of the semiconductor die 20 and the row of the bond pads 22a-22g is in parallel with the two rows of the bond fingers 12a-12d and 14a-14d.

The semiconductor die 20 further comprises two rows of dummy bond pads 112a-112d and 114a-114d. Likewise, the dummy bond pads 112a-112d are aligned in a straight line along the reference y-axis, and the row of the dummy bond pads 112a-112d is disposed between the row the bond pads 22a-22h and the row of the bond fingers 12a-12d from top view. The dummy bond pads 114a-114d are aligned in a straight line along the reference y-axis and the row of the dummy bond pads 114a-114d is disposed between the row of the bond pads 22a-22h and the row of the bond fingers 14a-14d from top view. These dummy bond pads 112a-112d and 114a-114d are electrically floating pads, which are fabricated concurrently with the fabrication process of the active bond pads 22a-22g. The term “electrically floating” as used herein means that there is no electrical connection for establishing a specific voltage on the dummy bond pads 112a-112d and 114a-114d.

According to this embodiment, each of the dummy bond pads 112a-112d and 114a-114d has a dimension that is larger than that of each of the bond pads 22a-22h. Preferably, each of the dummy bond pads 112a-112d and 114a-114d has an adequate surface area for accommodating and bonding two bonding wires at the same time. For example, each of the dummy bond pads 112a-112d and 114a-114d has a dimension of about 100 μm×60 μm, while each of the bond pads 22a-22h has a dimension of about 50 μm×60 μm.

According to this embodiment, a plurality of bonding wires 32a-32d are provided to electrically connect the bond pads 22b, 22d, 22f and 22h with the corresponding dummy bond pads 112a-112d respectively, and a plurality of bonding wires 42a-42d are provided to electrically connect the dummy bond pads 112a-112d with the corresponding bond fingers 12a-12d respectively. According to this embodiment, likewise, a plurality of bonding wires 34a-34d are provided to electrically connect the bond pads 22a, 22c, 22e and 22g with the corresponding dummy bond pads 114a-114d respectively, and a plurality of bonding wires 44a-44d are provided to electrically connect the dummy bond pads 114a-114d with the corresponding bond fingers 14a-14d respectively. The bonding wires 32a-32d, 34a-34d, 42a-42d and 44a-44d may be gold wires or copper wires.

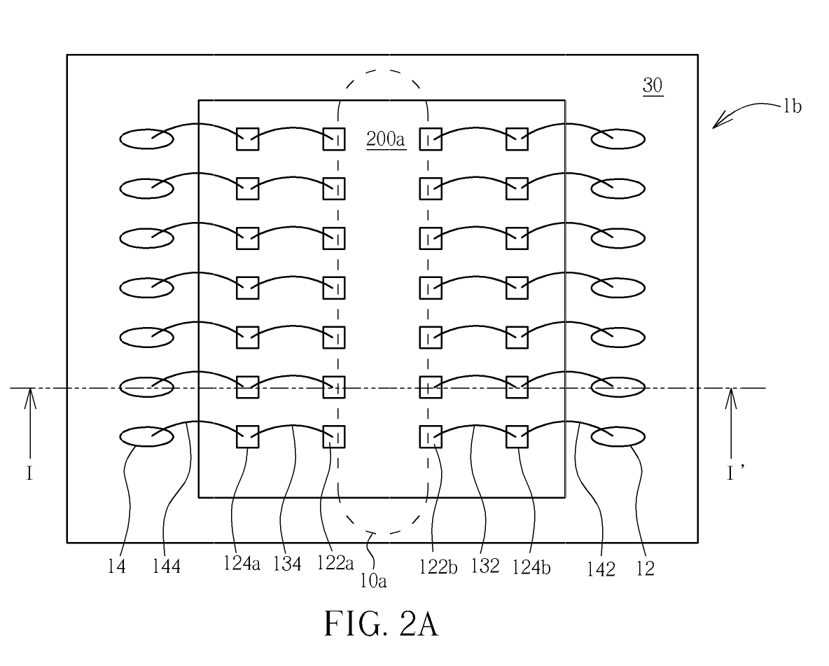

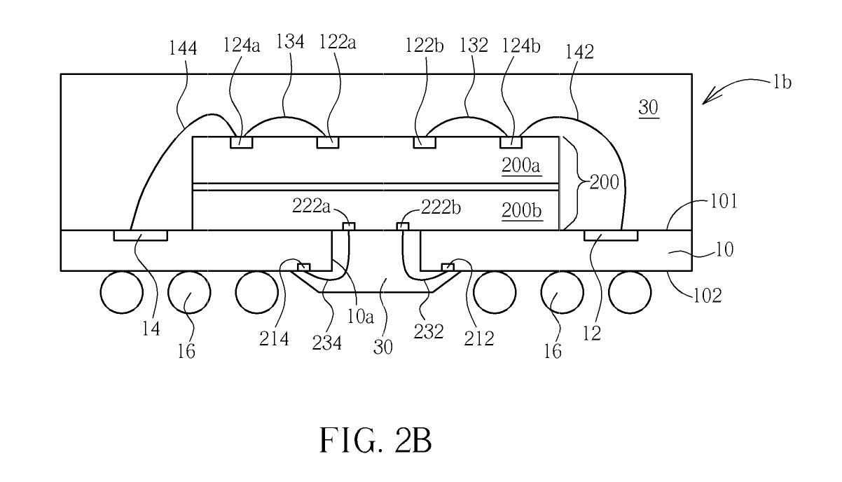

Please refer to FIG. 2A and FIG. 2B. FIG. 2A is a schematic top view of a three-dimensional (3D) semiconductor package in accordance with another embodiment of this invention, wherein like numeral numbers designate like devices, layers or regions. FIG. 2B is a schematic, cross-sectional view taken along line I-I′ of FIG. 2A. As shown in FIGS. 2A and 2B, a semiconductor package 1b includes a carrier substrate 10 such as a conventional package substrate, a multiple-die stack 200 including an upper die 200a and lower die 200b mounted on a top surface 101 of the carrier substrate 10, and a molding compound 30 encapsulating the multiple die stack 200.

At least two rows of bond fingers 12 and 14 are provided on the top surface 101 of the carrier substrate 10. According to this embodiment, the bond fingers 12 are aligned in a straight line at one side edge of the multiple-die stack 200. The bond fingers 14 are aligned in a row at another side edge of the multiple-die stack 200 opposite to the row of the bond fingers 12. An opening or slot 10a is provided at the center of the carrier substrate 10. Two rows of bond fingers 232 and 234 are provided on the bottom surface 102 of the carrier substrate 10 along two opposite sides of the slot 10a. The two rows of bond fingers 232 and 234 are disposed adjacent to the slot 10a. An array of solder balls 16 is provided on the bottom surface 102 of the carrier substrate 10. The semiconductor package shown in FIG. 2A and FIG. 2B is also known as window BGA or wBGA package.

According to this embodiment, the lower die 200b has an active bonding surface facing toward the top surface 101 of the carrier substrate 10. Two rows of bond pads 222a and 222b are provided at the center of the active bonding surface of the lower die 200b. A plurality of bonding wires 232 and 234 are provided to electrically connect the two rows of bond pads 222a and 222b with corresponding bond fingers 212 and 214 respectively. The bond pads 222a and 222b, the bonding wires 232 and 234, and the bond fingers 212 and 214 are encapsulated by molding compound 30 that also fills up the slot 10a.

According to this embodiment, bond pads 122a-122b, which are arranged in two rows, are provided on an active top surface of the upper die 200a. According to this embodiment, the bond pads 122a are aligned in a straight line and the row of the bond pads 122a is in parallel with the two rows of the bond fingers 12 and 14. The upper die 200a further comprises two rows of dummy bond pads 124a and 124b.

The dummy bond pads 124a are aligned in a straight line. The row of the dummy bond pads 124a is disposed between the row the bond pads 122a and the row of the bond fingers 14 from top view. The dummy bond pads 124b are aligned in a straight line, and the row of the dummy bond pads 124b is disposed between the row of the bond pads 122b and the row of the bond fingers 12 from top view.

According to this embodiment, each of the dummy bond pads 124a and 124b has a dimension that is larger than that of each of the bond pads 122a-122b. Preferably, each of the dummy bond pads 124a and 124b has an adequate surface area for accommodating two bonding wires. For example, each of the dummy bond pads 124a and 124b has a dimension of about 50 μm×60 μm, while each of the bond pads 122a-122b has a dimension of about 100 μm×60 μm.

According to this embodiment, a plurality of bonding wires 132 are provided to electrically connect the bond pads 122b with the corresponding dummy bond pads 124b respectively, and a plurality of bonding wires 142 are provided to electrically connect the dummy bond pads 124b with the corresponding bond fingers 12 respectively. According to this embodiment, likewise, a plurality of bonding wires 134 are provided to electrically connect the bond pads 122a with the corresponding dummy bond pads 124a respectively, and a plurality of bonding wires 144 are provided to electrically connect the dummy bond pads 124a with the corresponding bond fingers 14 respectively.

Those skilled in the art will readily observe that numerous modifications and alterations of the device and method may be made while retaining the teachings of the invention.

What is claimed is:

1. A semiconductor package comprising:
a carrier substrate having thereon at least one bond finger;
a semiconductor die mounted on a top surface of the carrier substrate;
at least one active bond pad disposed on the semiconductor die;
at least one dummy bond pad disposed on the semiconductor die;
a first bonding wire extending between the at least one active bond pad and the at least one dummy bond pad;
a second bonding wire extending between the at least one dummy bond pad and the at least one bond finger; and
a molding compound encapsulating at least the semiconductor die.

2. The semiconductor package according to claim 1 wherein the at least one dummy bond pad has a dimension that is larger than that of the at least one active bond pad.

3. The semiconductor package according to claim 1 wherein the at least one dummy bond pad has a dimension of about 100 μm×60 μm.

4. The semiconductor package according to claim 3 wherein the at least one active bond pad has a dimension of about 50 μm×60 μm.

5. The semiconductor package according to claim 1 wherein the at least one dummy bond pad has an adequate surface area for bonding the first and second bonding wires.

6. The semiconductor package according to claim 1 wherein the at least one dummy bond pad is electrically floating.

7. A semiconductor package comprising:
a carrier substrate having thereon at least one bond finger;
a multiple-die stack comprising a first semiconductor die mounted on a top surface of the carrier substrate, and a second semiconductor die stacked on the first semiconductor die;
at least one active bond pad disposed on the second semiconductor die;
at least one dummy bond pad disposed on the second semiconductor die;
a first bonding wire extending between the at least one active bond pad and the at least one dummy bond pad;
a second bonding wire extending between the at least one dummy bond pad and the at least one bond finger; and
a molding compound encapsulating at least the multiple-die stack.

8. The semiconductor package according to claim 7 wherein the at least one dummy bond pad has a dimension that is larger than that of the at least one active bond pad.

9. The semiconductor package according to claim 7 wherein the at least one dummy bond pad has a dimension of about 100 μm×60 μm.

10. The semiconductor package according to claim 9 wherein the at least one active bond pad has a dimension of about 50 μm×60 μm.

11. The semiconductor package according to claim 7 wherein the at least one dummy bond pad has an adequate surface area for bonding the first and second bonding wires.

12. The semiconductor package according to claim 7 wherein the at least one dummy bond pad is electrically floating.

13. The semiconductor package according to claim 7 wherein the first semiconductor die is wire bonded to a bottom surface of the carrier substrate through an opening of the carrier substrate.
